(19) United States
(12) Patent Application Publication
(10) Pub. No.: US 2021/0326557 A1
(43) Pub. Date: Oct. 21, 2021

(54) ELECTRONIC DEVICE HAVING A FINGERPRINT SENSING FUNCTION

(71) Applicant: Egis Technology Inc., Taipei (TW)

(72) Inventors: Su Kil Lee, Taipei (TW); Jun Tai Park, Taipei (TW)

(73) Assignee: Egis Technology Inc., Taipei (TW)

(21) Appl. No.: 17/143,155

(22) Filed: Jan. 7, 2021

Related U.S. Application Data
(60) Provisional application No. 63/010,053, filed on Apr. 15, 2020.
(60) Provisional application No. 63/021,071, filed on May 6, 2020.

(51) Int. Cl. G06K 9/00; G09F 9/30

(52) U.S. Cl. CPC G06K 9/0004; G09F 9/301; G06K 9/00053

(57) ABSTRACT

An electronic device having a fingerprint sensing function is provided. The electronic device includes a flexible display panel, an image sensor, and a hard protective film. The flexible display panel has a fingerprint sensing area. The image sensor is disposed under the flexible display panel and below the fingerprint sensing area. The hard protective film is disposed between the flexible display panel and the image sensor and under the fingerprint sensing area.

### CROSS-REFERENCE TO RELATED APPLICATION

This application claims the priority benefit of U.S. provisional application Ser. No. 63/010,053, filed on Apr. 15, 2020, and U.S. provisional application Ser. No. 63/021,071, filed on May 6, 2020. The entirety of each of the above-mentioned patent application is hereby incorporated by reference herein and made a part of this specification.

### BACKGROUND OF THE INVENTION

### 1. Field of the Invention

The invention generally relates to an electronic device and, in particular, to an electronic device having a fingerprint sensing function.

### 2. Description of Related Art

In a conventional electronic device having a touch screen and a under-display fingerprint sensing function, a cover glass is disposed on an organic light-emitting diode (OLED) display panel to protect the display panel and the fingerprint sensor. Recently, the electronic device is developed to be flexible, rollable, or foldable. In order to allow the electronic device to be flexible, rollable, or foldable, the cover glass is removed from the electronic device.

However, when the flexible, rollable, or foldable electronic device is equipped with a fingerprint sensor under the OLED display panel, and when a finger of a user press the bare OLED display panel without a cover glass thereon, the bare OLED display panel will be curved and touch the optical film of the fingerprint sensor, which may damage the optical film or crack the fingerprint sensor.

### SUMMARY OF THE INVENTION

Accordingly, the invention is directed to an electronic device having a fingerprint sensing function, which is flexible, rollable, or foldable and has high reliability.

According to an embodiment of the invention, an electronic device having a fingerprint sensing function is provided. The electronic device includes a flexible display panel, an image sensor, and a hard protective film. The flexible display panel has a fingerprint sensing area. The image sensor is disposed under the flexible display panel and below the fingerprint sensing area. The hard protective film is disposed between the flexible display panel and the image sensor and under the fingerprint sensing area.

In the electronic device having a fingerprint sensing function according to the embodiment of the invention, since a hard protective film is disposed between the flexible display panel and the image sensor and under the fingerprint sensing area, when the flexible display panel is curved by a finger of a user, the hard protective film will protect the image sensor thereunder from being damaged or cracked. As a result, the electronic device having a fingerprint sensing function according to the embodiment of the invention is flexible, rollable, or foldable and has high reliability.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of an electronic device having a fingerprint sensing function according to an embodiment of the invention.

FIG. 2 is a schematic cross-sectional view of an electronic device having a fingerprint sensing function according to another embodiment of the invention.

FIG. 3 is a schematic cross-sectional view of an electronic device having a fingerprint sensing function according to another embodiment of the invention.

FIG. 4A is a schematic cross-sectional view of an electronic device having a fingerprint sensing function according to another embodiment of the invention.

FIG. 4B is a schematic top view of the electronic device in FIG. 4A.

FIG. 5 is a schematic cross-sectional view of an electronic device having a fingerprint sensing function according to another embodiment of the invention.

FIG. 6 is a schematic cross-sectional view of an image sensor, an optical clear adhesive, an optical film, a COF package, and an FPC according to another embodiment of the invention.

FIG. 7A, FIG. 7B, and FIG. 7C show three types of the electronic device which the electronic device having a fingerprint sensing function can be applied to.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

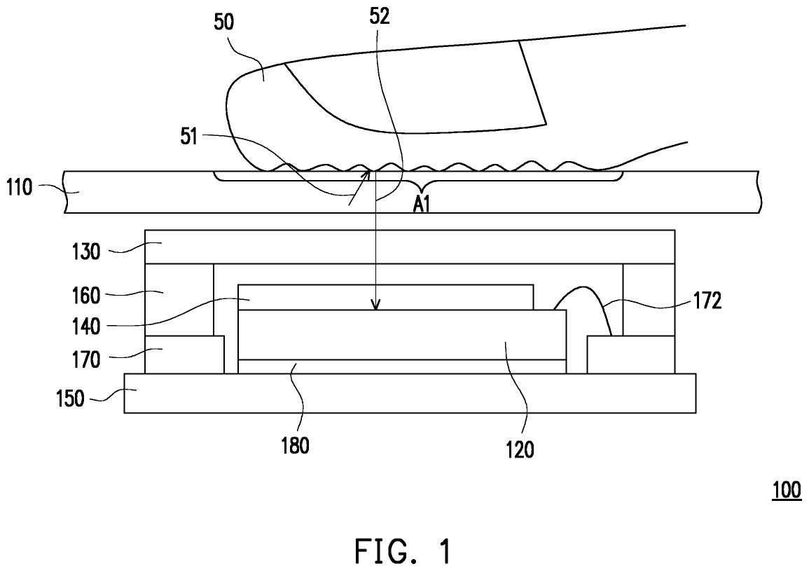

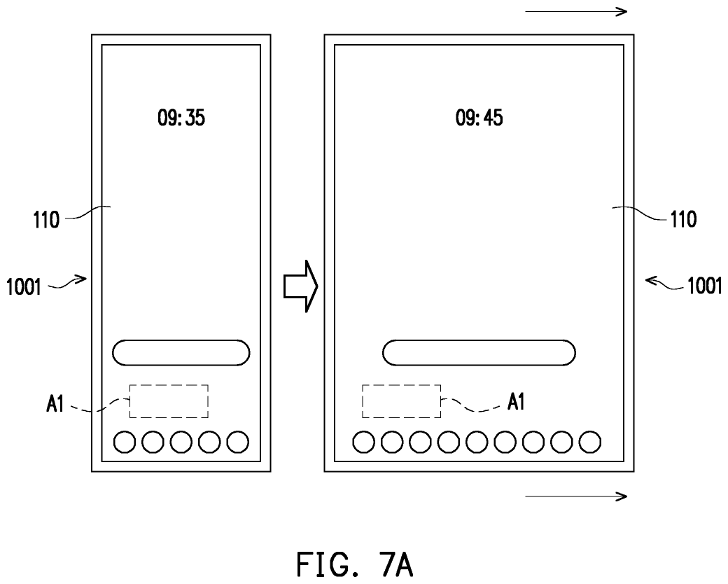

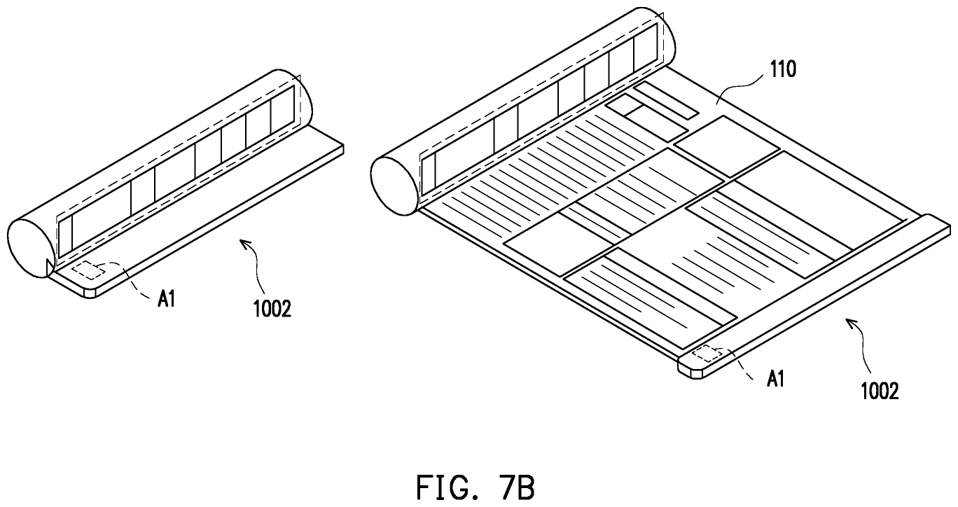

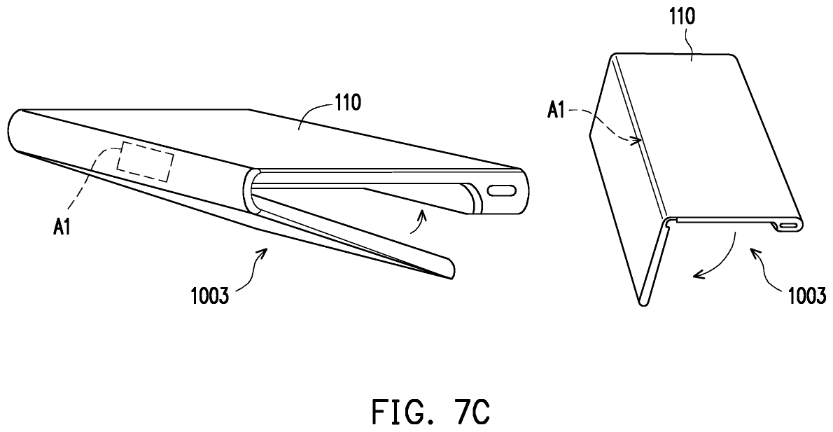

FIG. 1 is a schematic cross-sectional view of an electronic device having a fingerprint sensing function according to an embodiment of the invention. FIG. 7A, FIG. 7B, and FIG. 7C show three types of the electronic device which the electronic device having a fingerprint sensing function can be applied to. Referring to FIG. 1, the electronic device 100 having a fingerprint sensing function in this embodiment includes a flexible display panel 110, an image sensor 120, and a hard protective film 130. In this embodiment, the flexible display panel 110 is an organic light-emitting diode (OLED) display panel. However, in other embodiment, the flexible display panel 110 may be a liquid crystal display panel, an electrophoretic display panel, a micro-light-emitting-diode (micro-LED) display panel, or any other appropriate display panel. In this embodiment, the flexible display panel 110 has a fingerprint sensing area A1 configured to be pressed by a finger of a user. The image sensor 120 is disposed under the flexible display panel 110 and below the fingerprint sensing area A1. In this embodiment, the image sensor 120 is a complementary metal oxide semiconductor (CMOS) image sensor. However, in other embodiments, the image sensor 120 may be a charge coupled device (CCD). The hard protective film 130 is disposed between the flexible display panel 110 and the image sensor 120 and under the fingerprint sensing area A1. In other words, the hard protective film 130 is just under a part of the flexible display panel 110, but does not extend over the whole flexible display panel 110. In this embodiment, the hard protective film 130 is a transparent plate, for example, a glass plate. However, in other embodiments, the hard protective film 130 may be a transparent plastic plate. In an embodiment, whether the hard protective film 130 is a glass plate or a transparent plastic plate, the hard protective film is capable of enduring at least 200 gram pressing force from the fingerprint sensing area A1. For example, the hard protective film 130 is a Gorilla Glass plate. In an embodiment, an anti-reflection coating may be on at least one of a top surface and a bottom surface of the hard protective film 130. In an embodiment, an infrared cut-off coating may be on at least one of the top surface and the bottom surface of the hard protective film 130.

In this embodiment, the electronic device 100 further includes an optical layer 140 disposed on the image sensor 120 and between the hard protective film 130 and the image sensor 120. The optical layer 140 may include a collimator, a micro-lens array, an infrared cut-off filter, or any combination thereof.

In this embodiment, the electronic device 100 further includes a stiffener 150 and a spacer 160. The image sensor 120 is disposed on the stiffener 150, and the stiffener 150 is, for example, a metal plate. The spacer 160 is disposed on the stiffener 150, and carries the hard protective film 130. In this embodiment, the electronic device 100 further includes a flexible printed circuit (FPC) 170 disposed around the image sensor 120, and the spacer 160 is disposed on the flexible printed circuit 170. The FPC 170 is electrically connected to the image sensor 120. For example, the FPC 170 is electrically connected to the image sensor 120 through bonding wires 172. In this embodiment, the electronic device 100 further includes a die attaching film 180 to bond the image sensor 180 to the stiffener 150.

In this embodiment, pixels of the flexible display panel 110 emit an illumination light 51 to the finger 50, and the finger 50 reflects the illumination light 51 into a signal light 52 containing fingerprint information. The signal light 52 passes through the flexible display panel 110, the hard protective film 130, and the optical layer 140, and is then received by the image sensor 120 to form a fingerprint image on the image sensor 120. Therefore, the image sensor 120 can sense the fingerprint of the finger 50. In this embodiment, the electronic device 100 is, for example, a smartphone, a tablet computer, a notebook computer, a personal digital assistant (PDA), or any other appropriate electronic device.

In the electronic device 100 having a fingerprint sensing function according to this embodiment, since the hard protective film 130 is disposed between the flexible display panel 110 and the image sensor 120 and under the fingerprint sensing area A1, when the flexible display panel 110 is pressed and thus curved by a finger 50 of a user, the hard protective film 130 will protect the image sensor 120 and the optical layer 140 thereunder from being damaged or cracked. As a result, the electronic device 100 according to this embodiment is flexible, rollable, or foldable and has high reliability.

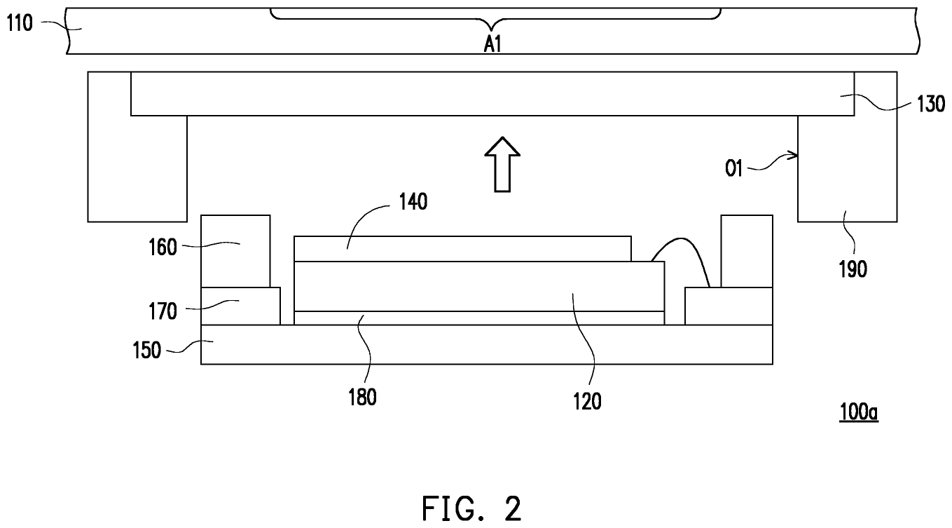

FIG. 2 is a schematic cross-sectional view of an electronic device having a fingerprint sensing function according to another embodiment of the invention. Referring to FIG. 2, the electronic device 100a in this embodiment is similar to the electronic device 100 in FIG. 1, and the main difference therebetween is as follows. In this embodiment, the electronic device 100a further includes a middle frame 190 supporting the hard protective film 130 and having an opening O1 to contain the image sensor 120. In this embodiment, the whole of the image sensor 120, the optical layer 140, the stiffener 150, the FPC 170, and the spacer 160 is assembled into the opening O1.

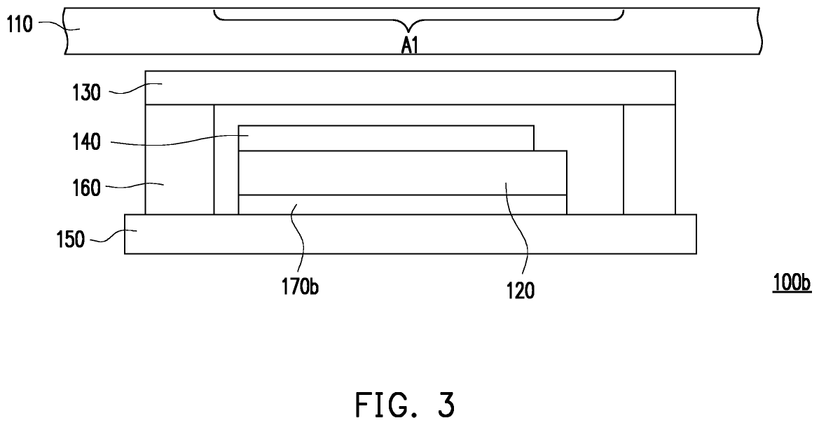

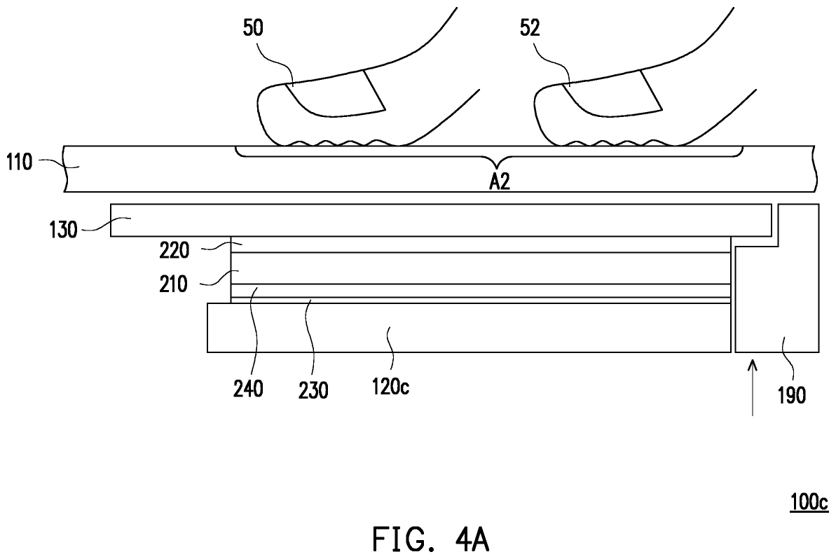

FIG. 3 is a schematic cross-sectional view of an electronic device having a fingerprint sensing function according to another embodiment of the invention. Referring to FIG. 3, the electronic device 100b in this embodiment is similar to the electronic device 100 in FIG. 1, and the main difference therebetween is as follows. In the electronic device 100b according to this embodiment, the FPC 170b is disposed between the image sensor 120 and the stiffener 150, and carries the image sensor 120. In other words, the image sensor 120 is disposed on the stiffener 150 through the FPC 170b.

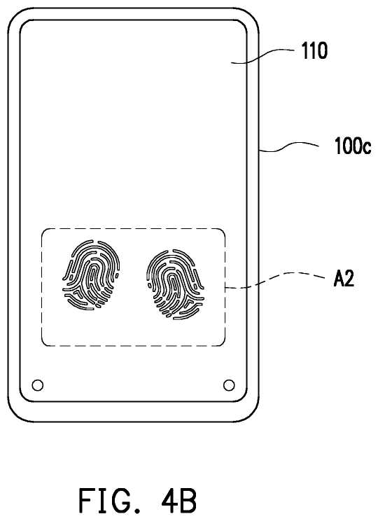

FIG. 4A is a schematic cross-sectional view of an electronic device having a fingerprint sensing function according to another embodiment of the invention, and FIG. 4B is a schematic top view of the electronic device in FIG. 4A. Referring to FIG. 4A and FIG. 4B, the electronic device 100c in this embodiment is similar to the electronic device 100 in FIG. 1, and the main difference therebetween is as follows. In the electronic device 100c according to this embodiment, the image sensor 120c is a thin film transistor (TFT) sensor, and the fingerprint sensing area A2 corresponding to the TFT sensor is capable of containing a plurality of fingerprints; for example, two fingerprints (the fingerprint of the finger 50 and the fingerprint of the finger 52) are exemplarily shown in FIG. 4A and FIG. 4B. A controller electrically connected to the image sensor 120c can be configured to identify a plurality of fingerprints in an image frame obtained by the image sensor 120c.

Moreover, in this embodiment, the electronic device 100c further includes an optical film 210, an optical clear adhesive or resin film 220, an optical clear adhesive 240, an infrared cut-off filter 230, and a middle frame 190. The optical film 210 is disposed on the image sensor 120c, wherein the optical film 210 includes a collimator, a micro-lens array, or a combination thereof. The optical clear adhesive or resin film 220 is configured between the optical film 210 and the hard protective film 130. When the optical film 210 is a micro-lens array, the refractive index of the optical clear adhesive or resin film 220 is suggested to get a lower refractive index value close to the refractive index of air so as to enhance micro-lens array performance. The optical clear adhesive 240 is connected between the optical film 210 and the image sensor 120c. The infrared cut-off filter 230 is disposed on the image sensor 120c. In this embodiment, the optical clear adhesive 240 is connected between the optical film 210 and the infrared cut-off filter 230. Moreover, the middle frame 190 supports the hard protective film 130. In this embodiment, the hard protective film 130 is under a part of the flexible display panel 110, but does not extend over the whole flexible display panel 110.

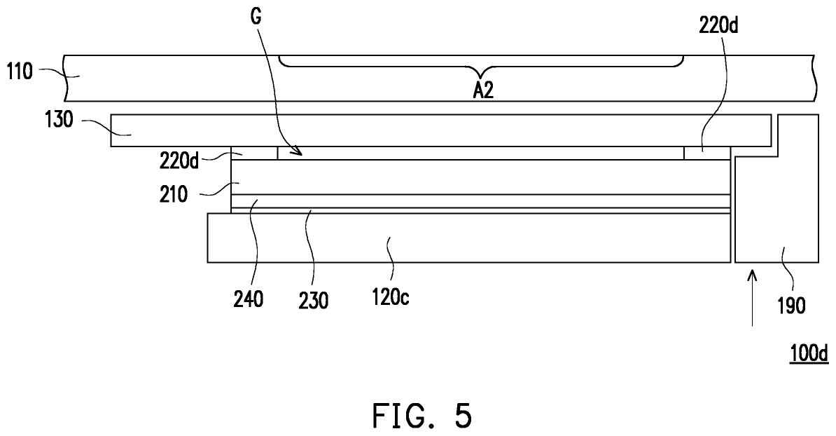

FIG. 5 is a schematic cross-sectional view of an electronic device having a fingerprint sensing function according to another embodiment of the invention. Referring to FIG. 5, the electronic device 100d in this embodiment is similar to the electronic device 100c in FIG. 4A, and the main difference is as follows. In FIG. 4A, there is no air gap between the hard protective film 130 and the optical film 210. However, in the electronic device 100d in this embodiment shown in FIG. 5, an adhesive spacer 220d is adopted to replace the optical clear adhesive or resin film 220 in FIG. 4A. The adhesive spacer 220d is connected between the optical film 210 and the hard protective film 130 and forming an air gap G between the optical film 210 and the hard protective film 130. The thickness of the air gap G is, for example, 50 to 300 microns.

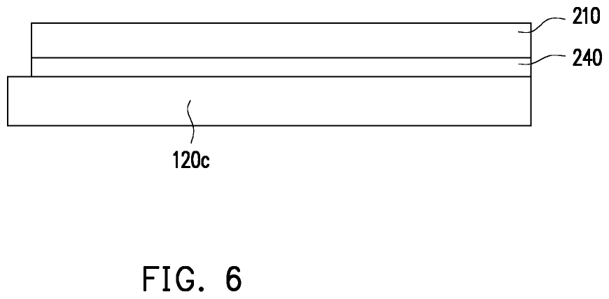

FIG. 6 is a schematic cross-sectional view of an image sensor, an optical clear adhesive, an optical film, a COF package, and an FPC according to another embodiment of the invention. The image sensor 120c, the infrared cut-off filter 230, the optical clear adhesive 240, and the optical film 210 in FIG. 4A or FIG. 5 may be changed into the image sensor 120c, the optical clear adhesive 240, and the optical film 210 in FIG. 6 to form two other types of the electronic device. That is to say, there is no infrared cut-off filter in this embodiment, and the optical clear adhesive 240 bonds the optical film 210 to the image sensor 120c.

FIG. 7A and FIG. 7B show an electronic device 1001 and an electronic device 1002 which are rollable and are rolled up in the left and spread up in the right. FIG. 7C shows an electronic device 1003 which is foldable, and is folded in the left and unfolded in the right. It can be learned from FIG. 7A to FIG. 7C that the fingerprint sensing area A1 is located at a region which is not bent or curved. In a similar manner, the sensing area A2 in the embodiments of FIG. 4A, FIG. 4B, and FIG. 5 may also be located at a region which is not bent or curved as shown in FIG. 7A to FIG. 7C.

In conclusion, in the electronic device having a fingerprint sensing function according to the embodiment of the invention, since a hard protective film is disposed between the flexible display panel and the image sensor and under the fingerprint sensing area, when the flexible display panel is curved by a finger of a user, the hard protective film will protect the image sensor thereunder from being damaged or cracked. As a result, the electronic device having a fingerprint sensing function according to the embodiment of the invention is flexible, rollable, or foldable and has high reliability.

It will be apparent to those skilled in the art that various modifications and variations can be made to the structure of the invention without departing from the scope or spirit of the invention. In view of the foregoing, it is intended that the invention covers modifications and variations of this invention provided they fall within the scope of the following claims and their equivalents.

What is claimed is:

1. An electronic device having a fingerprint sensing function, the electronic device comprising:
a flexible display panel having a fingerprint sensing area;
an image sensor disposed under the flexible display panel and below the fingerprint sensing area; and
a hard protective film disposed between the flexible display panel and the image sensor and under the fingerprint sensing area.

2. The electronic device according to claim 1 further comprising an optical layer disposed on the image sensor and between the hard protective film and the image sensor.

3. The electronic device according to claim 1, wherein the hard protective film is a glass plate or a transparent plastic plate.

4. The electronic device according to claim 1 further comprising:
a stiffener, wherein the image sensor is disposed on the stiffener; and
a spacer disposed on the stiffener, wherein the hard protective film is disposed on the spacer.

5. The electronic device according to claim 4 further comprising a flexible printed circuit disposed around the image sensor, wherein the spacer is disposed on the flexible printed circuit.

6. The electronic device according to claim 4 further comprising a flexible printed circuit disposed between the image sensor and the stiffener, and the image sensor is disposed on the stiffener through the flexible printed circuit.

7. The electronic device according to claim 1 further comprising a middle frame supporting the hard protective film and having an opening to contain the image sensor.

8. The electronic device according to claim 1, wherein the hard protective film is capable of enduring at least 200 gram pressing force from the fingerprint sensing area.

9. The electronic device according to claim 1, wherein the image sensor is a thin film transistor sensor.

10. The electronic device according to claim 9, wherein the fingerprint sensing area corresponding to the thin film transistor sensor is capable of containing a plurality of fingerprints.

11. The electronic device according to claim 9 further comprising:
an optical film disposed on the image sensor, wherein the optical film comprising a collimator, a micro-lens array, or a combination thereof.

12. The electronic device according to claim 11 further comprising an optical clear adhesive or resin film configured between the optical film and the hard protective film.

13. The electronic device according to claim 11 further comprising an optical clear adhesive connected between the optical film and the image sensor.

14. The electronic device according to claim 11 further comprising:
an infrared cut-off filter disposed on the image sensor.

15. The electronic device according to claim 11 further comprising an optical clear adhesive connected between the optical film and the infrared cut-off filter.

16. The electronic device according to claim 11 further comprising a middle frame supporting the hard protective film.

17. The electronic device according to claim 11 further comprising an adhesive spacer connected between the optical film and the hard protective film and forming an air gap between the optical film and the hard protective film.

18. The electronic device according to claim 1, wherein the hard protective film is a transparent plate.

19. The electronic device according to claim 1, wherein the flexible display panel is an organic light-emitting diode display panel.
